(19) United States
(12) Patent Application Publication
(10) Pub. No.: US 2008/0265432 A1
(43) Pub. Date: Oct. 30, 2008

(54) MULTI-CHIP PACKAGE AND METHOD OF MANUFACTURING THE MULTI-CHIP PACKAGE

(75) Inventors: Min-Ho O, Daegu (KR); Eun-Chul AHN, Gyeonggi-do (KR); Jong-Ho LEE, Chungcheongnam-do (KR); Pyoung-Wan KIM, Gyeonggi-do (KR); Hyeon HWANG, Gyeonggi-do (KR); Teak-Hoon LEE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/113,009

(22) Filed: Apr. 30, 2008

(30) Foreign Application Priority Data
Apr. 30, 2007 (KR) 2007-42038

(51) Int. Cl. H01L 23/49

(52) U.S. Cl. 257/777; 257/E23.024

(57) ABSTRACT

A multi-chip package includes a mounting substrate, a first semiconductor chip, a second semiconductor chip, a reinforcing member, conductive wires and an encapsulant. The first semiconductor chip is disposed on the mounting substrate. The second semiconductor chip is disposed on the first semiconductor chip. An end portion of the second semiconductor chip protrudes from a side portion of the first semiconductor chip. A reinforcing member is disposed on an overlapping region of the second semiconductor chip where the second semiconductor chip overlaps with the side portion of the first semiconductor chip such that the reinforcing member decreases downward bending of the second semiconductor chip from the side portion of the first semiconductor chip. The conductive wires electrically connect the first and second semiconductor chips to the mounting substrate. The encapsulant is disposed on the mounting substrate to cover the first and second semiconductor chips and the conductive wires.

### CROSS-REFERENCE TO RELATED APPLICATIONS

This application claims priority under 35 U.S.C. §119 to Korean Patent Application No. 2007-42038, filed on Apr. 30, 2007 in the Korean Intellectual Property Office (KIPO), the contents of which are herein incorporated by reference in their entirety.

### BACKGROUND

1. Technical Field

Example embodiments of the present invention relate to a multi-chip package and a method of manufacturing the multi-chip package. More particularly, example embodiments of the present invention relate to a multi-chip package including a semiconductor chip having a reinforced overhang structure and a method of manufacturing the multi-chip package.

2. Description of the Related Art

Nowadays, semiconductor packages are becoming smaller, thinner and lighter weight according to the trend towards miniaturization of various electronic products using semiconductor devices. In the past, a single chip package where only one semiconductor chip is mounted in one semiconductor package was conventionally employed. More recently, a multi-chip package where various semiconductor chips are mounted in one semiconductor package is increasingly employed. Particularly, portable information/communication devices such as personal digital assistants (PDAs) or cellular phones, which are increasing in demand, may require complex products capable of simultaneously performing various functions.

Accordingly, in a manufacturing process of the multi-chip package, one matter of concern may be how many semiconductor chips capable of performing different functions can be mounted in one standardized semiconductor package. Thus, a chip stack package where a plurality of semiconductor chips is vertically stacked to form a unit semiconductor package has been developed. The chip stack package may be more advantageous for manufacturing small and lightweight semiconductor packages than a package including several single chip packages where only one semiconductor chip is mounted in each semiconductor package.

However, the chip stack package may have a problem in that the semiconductor chips are stacked and therefore there is an increase the thickness of the package. Thus, in order to manufacture thinner packages, the semiconductor chips need to be made thinner. However, a thin semiconductor chip may have another problem as described below.

Since semiconductor chips having different sizes are mounted in one chip stack package, an upper stacked semiconductor chip on a lower stacked semiconductor chip has an overhang portion that protrudes from a side portion of the lower stacked semiconductor chip. Therefore, after the semiconductor chips are stacked on a mounting substrate, cracks may be generated in the overhang portion of the upper stacked semiconductor chip during a wire bonding process.

FIG. 1 is a cross-sectional view illustrating a wire bonding process of a conventional multi-chip package having an overhang structure.

Referring to FIG. 1, a conventional multi-chip package 10 has a stacked structure where a first semiconductor chip 20 and a second semiconductor chip 30 are stacked on a mounting substrate 12. A size of the second semiconductor chip 30 may be substantially larger than that of the first semiconductor chip 20. Alternatively, the second semiconductor chip 30 may have about the same size the as the first semiconductor chip 20, but be arranged in a different direction from the first semiconductor chip 20. Thus, the second semiconductor chip 30 has an overhang portion (P) protruding from a side portion of the first semiconductor chip 20.

An input/output (I/O) pad 32 is formed on an active surface of the second semiconductor chip 30. The input/output pad 32 is formed on the overhang portion of the second semiconductor chip 30. Also, a bond finger 14 is formed on an upper surface of the mounting substrate 12.

After the first and the second semiconductor chips 20 and 30 are adhered to the mounting substrate 12 by a die bonding process, the first and the second semiconductor chips 20 and 30 are electrically connected to the mounting substrate 12 by a wire bonding process. By performing the wire bonding process, both end portions of a bonding wire 42 are adhered to the input/output pad 32 of the second semiconductor chip 30 and the bond finger 14 of the mounting substrate 12, respectively.

For example, an end portion of the bonding wire 42 is adhered to the input/output pad 32 of the second semiconductor chip 30 by a bonding capillary 40. As part of the wire bonding process, the bonding capillary 40 may apply pressure to the overhang portion (P) of the second semiconductor chip 30. As the overhang portion (P) protrudes from the side portion of the first semiconductor chip 20, the overhang portion (P) of the second semiconductor chip 30 flexes up and down. As a protruding distance of the overhang portion (P) becomes longer and the semiconductor chip becomes thinner, the flexing of the overhang portion (P) is increased and can cause a crack (C) in the second semiconductor chip 30.

### SUMMARY

Example embodiments of the present invention provide a multi-chip package where a crack is prevented from being generated during a wire bonding process. Example embodiments of the present invention also provide a method of manufacturing the above-mentioned multi-chip package.

According to one aspect of the present invention, a multi-chip package includes a mounting substrate, a first semiconductor chip, a second semiconductor chip, a reinforcing member, conductive wires and an encapsulant. The first semiconductor chip is disposed on the mounting substrate. The second semiconductor chip is disposed on the first semiconductor chip. An end portion of the second semiconductor chip protrudes from a side portion of the first semiconductor chip. The reinforcing member is disposed on an overlapping region of the second semiconductor chip where the second semiconductor chip overlaps with the side portion of the first semiconductor chip such that the reinforcing member decreases downward bending of the second semiconductor chip from the side portion of the first semiconductor chip. The conductive wires electrically connect the first and the second semiconductor chips to the mounting substrate. The encapsulant is disposed on the mounting substrate to cover the first and second semiconductor chips and the conductive wires.

### BRIEF DESCRIPTION OF THE DRAWINGS

The above and other features and advantages of the present invention will become more apparent by describing in detail example embodiments thereof with reference to the accompanying drawings, in which:

FIG. 1 is a cross-sectional view illustrating a wire bonding process of a conventional multi-chip package having an overhang structure;

FIG. 2 is a plan view illustrating a multi-chip package in accordance with example embodiments of the present invention;

FIG. 3 is a cross-sectional view taken along the line I-I′ of FIG. 2;

FIGS. 4 and 5 are plan views illustrating multi-chip packages in accordance with other example embodiments of the present invention;

FIG. 6 is a plan view illustrating a multi-chip package in accordance with still another example embodiment of the present invention;

FIG. 7 is a cross-sectional view taken along the line II-II′ of FIG. 6; and

FIG. 8 is a flow chart illustrating a method of manufacturing the multi-chip package of FIG. 2.

### DETAILED DESCRIPTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

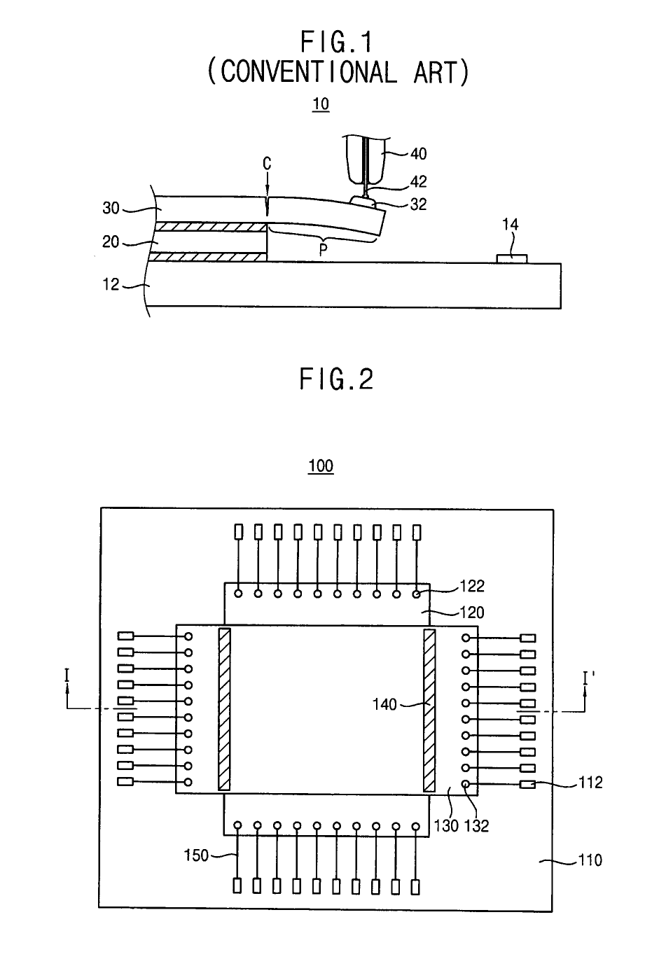

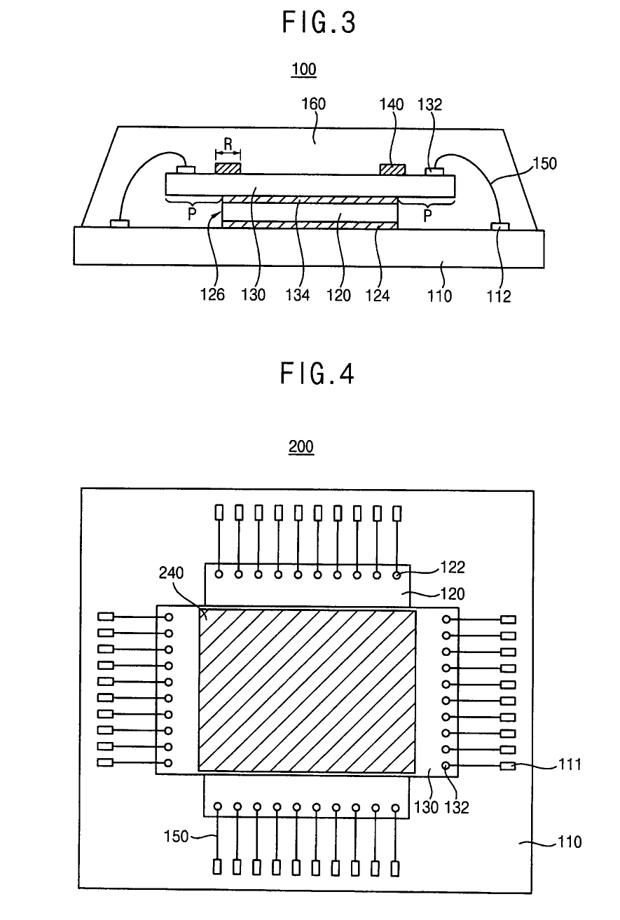

FIG. 2 is a plan view illustrating a multi-chip package in accordance with example embodiments of the present invention, and FIG. 3 is a cross-sectional view taken along the line I-I′ of FIG. 2.

Referring to FIGS. 2 and 3, a multi-chip package 100 according to example embodiments of the present invention includes a mounting substrate 110, and a first semiconductor chip 120 and a second semiconductor chip 130 sequentially stacked on the mounting substrate 110.

Bond fingers 112 for an electrical connection between the first and the second semiconductor chips 120 and 130 are formed on the mounting substrate 110. In one example embodiment, a solder ball pad (not illustrated) may be formed on an opposing surface of the mounting substrate 110, and the mounting substrate 110 may be a printed circuit board including a conductive structure such as a via formed therein.

The first semiconductor chip 120 is adhered to the mounting substrate 110 by a first adhesive layer 124. A first bonding pad 122 for an electrical connection to the mounting substrate 110 is formed on the first semiconductor chip 120. The second semiconductor chip 130 is adhered to the first semiconductor chip 120 by a second adhesive layer 134. A second bonding pad 132 for an electrical connection to the mounting substrate 110 is formed on the second semiconductor chip 130.

According to some embodiments, the first and the second semiconductor chips 120 and 130 may be adhered by a eutectic die bonding process, a soft solder die bonding process, a tape bonding process, etc. The first and the second adhesive layers 124 and 134 may include an epoxy material, polyimide, etc.

The second semiconductor chip 130 is arranged on the first semiconductor chip 120. In one example embodiment, a size of the second semiconductor chip 130 may be different from that of the first semiconductor chip 120. For example, the size of the second semiconductor chip 130 may be larger than that of the first semiconductor chip 120. Alternatively, the size of the second semiconductor chip 130 may be substantially the same as that of the first semiconductor chip 120. The first and the second semiconductor chips 120 and 130 may have a rectangular shape.

A longitudinal direction of the second semiconductor chip 130 may be substantially perpendicular to a longitudinal direction of the first semiconductor chip 120. The first and the second semiconductor chips 120 and 130 may cross each other, and thus, an end portion of the second semiconductor chip 130 may protrude from a side portion 126 of the first semiconductor chip 120. Accordingly, the second semiconductor chip 130 has an overhang portion (P) protruding from the first semiconductor chip 120.

A reinforcing member 140 is formed on the second semiconductor chip 130. In one example embodiment, the reinforcing member 140 may be formed on an overlapping region (R) of the second semiconductor chip 130 where the second semiconductor chip 130 overlaps with the side portion 126 of the first semiconductor chip 120. The overhang portion (P) of the second semiconductor chip 130 protrudes from the overlapping region (R) of the first and the second semiconductor chips 120 and 130.

In one example embodiment, a liquefied epoxy resin may be coated on the overlapping region (R) of the second semiconductor chip 130 to form the reinforcing member 140. Alternatively, an adhesive film may be coated on the overlapping region (R) of the second semiconductor chip 130 to form the reinforcing member 140.

The first bonding pad 122 of the first semiconductor chip 120 is electrically connected to the bond finger 112 of the mounting substrate 110 by one of the conductive wires 150. The second bonding pad 132 of the second semiconductor chip 130 is electrically connected to the bond finger 112 of the mounting substrate 110 by another one of the conductive wires 150. For example, the first and the second semiconductor chips 120 and 130 may be electrically connected to the mounting substrate 110 by a wire bonding process. The conductive wires may include a conductive material such as gold, aluminum, etc.

In one example embodiment, the second bonding pad 132 may be formed on the overhang portion (P) of the second semiconductor chip 130. In the wire bonding process, a bonding capillary is positioned over the second bonding pad 132 to adhere an end portion of a wire to the second bonding pad 132. Then, a ball is formed at the end portion of the wire by vibration and heat, and the ball of the wire is adhered to the second bonding pad 132. In this case, the reinforcing member 140 may prevent the overhang portion (P) from being downwardly bent due to pressure from the bonding capillary. Also, the reinforcing member 140 may decrease the flexing of the overhang portion (P) such that a crack is prevented from being generated adjacent to the overhang portion (P).

Further, the reinforcing member 140 may increase the strength of the overhang portion (P) of the second semiconductor chip 130. Because the reinforcing member 140 is formed on a portion where a crack is expected to be frequently generated, the reinforcing member 140 may be positioned to reinforce a vulnerable portion of the second semiconductor chip 130.

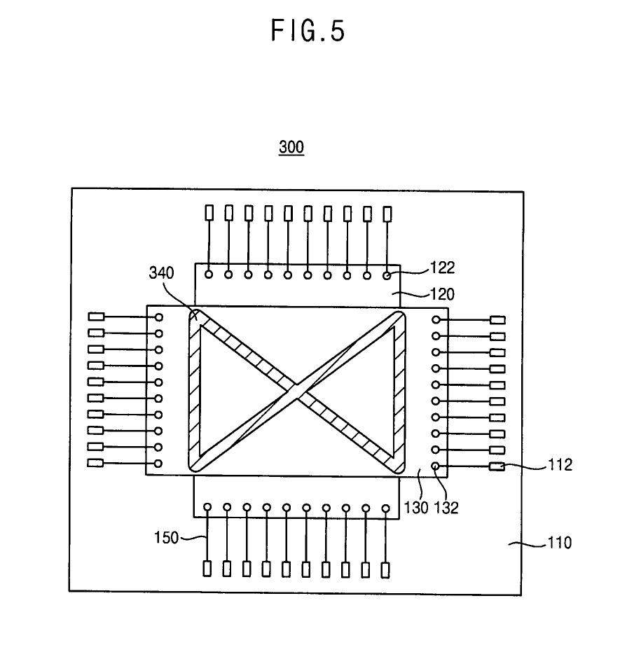

FIGS. 4 and 5 are plan views illustrating multi-chip packages in accordance with other example embodiments of the present invention. Multi-chip packages of the present embodiments may include elements substantially the same as those of the package in example embodiments of FIG. 2 except for a reinforcing member. Thus, the same reference numerals will be used to refer to the same or like elements as those described in example embodiments of FIG. 2 and any further explanation with respect to the same elements will be omitted.

As illustrated in FIG. 4, a reinforcing member 240 may be formed not only on a region of the second semiconductor chip 130 where the second semiconductor chip 130 overlaps with a side portion of the first semiconductor chip 120, but also on an substantially entire region of the second semiconductor chip 130 where the second semiconductor chip 130 overlaps with the first semiconductor chip 120. Alternatively, as illustrated in FIG. 5, a reinforcing member 340 may be formed not only on a region of the second semiconductor chip 130 where the second semiconductor chip 130 overlaps with a side portion of the first semiconductor chip 120, but also on a diagonal region of the second semiconductor chip 130 where the second semiconductor chip 130 overlaps with the first semiconductor chip 120.

The reinforcing members 240 and 340 may have various arrangements corresponding to a distance and thickness of the second semiconductor chip 130 arranged over the first semiconductor chip 120. Also, the reinforcing members 240 and 340 may have various thicknesses corresponding to a distance and thickness of the overhang portion.

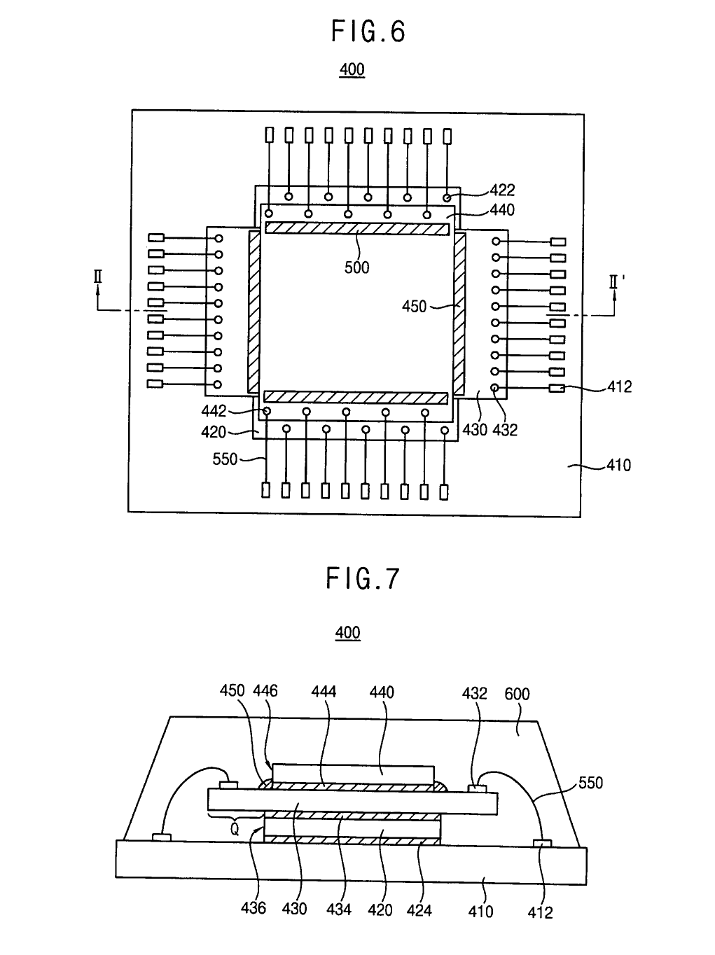

FIG. 6 is a plan view illustrating a multi-chip package in accordance with still another example embodiment of the present invention, and FIG. 7 is a cross-sectional view taken along the line II-II′ of FIG. 6. Multi-chip packages of the present embodiments may include elements substantially the same as those of the package in example embodiments of FIG. 2 except for a third semiconductor chip and an auxiliary reinforcing member. Thus, any further explanations with respect to the same elements will be omitted.

Referring to FIGS. 6 and 7, a multi-chip package 400 according to still another example embodiment of the present invention includes a mounting substrate 410, and a first semiconductor chip 420, a second semiconductor chip 430, and a third semiconductor chip 440 sequentially stacked on the mounting substrate 41 0. Bond fingers 412 for an electrical connection to the first, the second and the third semiconductor chips 420, 430 and 440 are formed on the mounting substrate 410.

The first semiconductor chip 420 is adhered to the mounting substrate 410 by a first adhesive layer 424. A first bonding pad 422 for an electrical connection to the mounting substrate 410 is formed on the first semiconductor chip 420. The second semiconductor chip 430 is adhered to the first semiconductor chip 420 by a second adhesive layer 434. A second bonding pad 432 for an electrical connection to the mounting substrate 410 is formed on the second semiconductor chip 430. The third semiconductor chip 440 is formed on the second semiconductor chip 420 by a third adhesive layer 444. A third bonding pad 442 for an electrical connection to the mounting substrate 410 is formed on the third semiconductor chip 440.

In another example embodiment, the first, the second and the third semiconductor chips 420, 430 and 440 may be adhered by a eutectic die bonding process, a soft solder die bonding process, a tape bonding process, etc. The first, the second and the third adhesive layers 424, 434 and 444 may include epoxy material, polyimide, etc.

The second semiconductor chip 430 is arranged on the first semiconductor chip 420. The third semiconductor chip 440 is arranged on the second semiconductor chip 430. In another example embodiment, a size of the second semiconductor chip 430 may be different from that of the first semiconductor chip 420. A size of the third semiconductor chip 440 may be different from that of the second semiconductor chip 430. For example, the size of the second semiconductor chip 430 may be larger than that of the first semiconductor chip 420, and the size of the second semiconductor chip 430 may be larger than that of the third semiconductor chip 440. Alternatively, the size of the second semiconductor chip 430 may be substantially the same as that of the first semiconductor chip 420, and the size of the second semiconductor chip 430 may be substantially the same as that of the third semiconductor chip 440. The first, the second and the third semiconductor chips 420, 430 and 440 may have a rectangular shape.

A longitudinal direction of the second semiconductor chip 430 may be substantially perpendicular to a longitudinal direction of the first semiconductor chip 420. A longitudinal direction of the third semiconductor chip 440 may be substantially perpendicular to the longitudinal direction of the second semiconductor chip 430. The first and the second semiconductor chips 420 and 430 may cross each other, and thus, an end portion of the second semiconductor chip 430 may protrude from a side portion 436 of the first semiconductor chip 420. The second and the third semiconductor chips 430 and 440 may cross each other, and thus, an end portion of the third semiconductor chip 440 may protrude from a side portion of the second semiconductor chip 430. The second semiconductor chip 430 has an overhang portion (Q) protruding from the first semiconductor chip 420. The third semiconductor chip 440 has an overhang portion protruding from the second semiconductor chip 430.

In another example embodiment, an auxiliary reinforcing member 450 may be formed on the overhang portion (Q) of the second semiconductor chip 430. The auxiliary reinforcing member 450 may make contact with a side portion 446 of the third semiconductor chip 440 on the overhang portion (Q) of the second semiconductor chip 430. Alternatively, the auxiliary reinforcing member 450 may be formed on the overhang portion (Q) of the second semiconductor chip 430. The auxiliary reinforcing member 450 may be arranged near the side portion 446 of the third semiconductor chip 440 on the overhang portion (Q) of the second semiconductor chip 430. For example, liquefied epoxy resin may be coated on the second semiconductor chip 430 to form the auxiliary reinforcing member 450.

A reinforcing member 500 may be formed on an overlapping region of the third semiconductor chip 440 where the third semiconductor chip 440 overlaps with a side portion of the second semiconductor chip 430.

The first bonding pad 422 of the first semiconductor chip 420 is electrically connected to the bond finger 412 of the mounting substrate 410 by one of the conductive wires 550. The second bonding pad 432 of the second semiconductor chip 430 is electrically connected to the bond finger 412 of the mounting substrate 410 by another one of the conductive wires 550. The third bonding pad 442 of the third semiconductor chip 440 is electrically connected to the bond finger 412 of the mounting substrate 410 by still another one of the conductive wires 550.

For example, the first, the second and the third semiconductor chips 420, 430 and 440 may be electrically connected to the mounting substrate 410 by a wire bonding process. The conductive wires 550 may include a conductive material such as gold, aluminum, etc.

In another example embodiment, the second bonding pad 432 may be formed on the overhang portion (Q) of the second semiconductor chip 430. The third bonding pad 442 may be formed on the overhang portion of the third semiconductor chip 440. In the wire bonding process, a bonding capillary is positioned over the second bonding pad 432 to adhere an end portion of a wire to the second bonding pad 432. Then, a ball is formed at the end portion of the wire by vibration and heat, and the ball of the wire is adhered to the second bonding pad 432. In this case, the auxiliary reinforcing member 450 may prevent the overhang portion (Q) from bending downward due to pressure of the bonding capillary. Also, the auxiliary reinforcing member 450 may decrease the flexing of the overhang portion (Q) such that a crack is prevented from being generated adjacent to the overhang portion (Q).

After the second bonding pad 430 is electrically connected to the bond finger 412 of the mounting substrate 410 by a wire bonding process, the bonding capillary is positioned over the third bonding pad 442 to adhere an end portion of a wire to the third bonding pad 442. Then, a ball is formed at the end portion of the wire by vibration and heat, and the ball of the wire is adhered to the third bonding pad 442. In this case, the reinforcing member 500 may decrease the flexing of the overhang portion of the third semiconductor chip 440 such that a crack is prevented from being generated adjacent to the overhang portion of the third semiconductor chip 440.

After the first, the second and the third semiconductor chips 420, 430 and 440 are electrically connected to the mounting substrate 410 by the conductive wires 550, a molding member or encapsulant 600 is formed on the mounting substrate 410 including the first, the second and the third semiconductor chips 420, 430 and 440 adhered thereto. The molding member 600 may protect the first, the second and the third semiconductor chips 420, 430 and 440 from various causes of electrical deterioration such as corrosion due to air or atmosphere and may provide mechanical stability.

For example, the molding member 600 may be formed using an epoxy mold compound (EMC).

Hereinafter, a method of manufacturing the multi-chip package of FIG. 2 will be described.

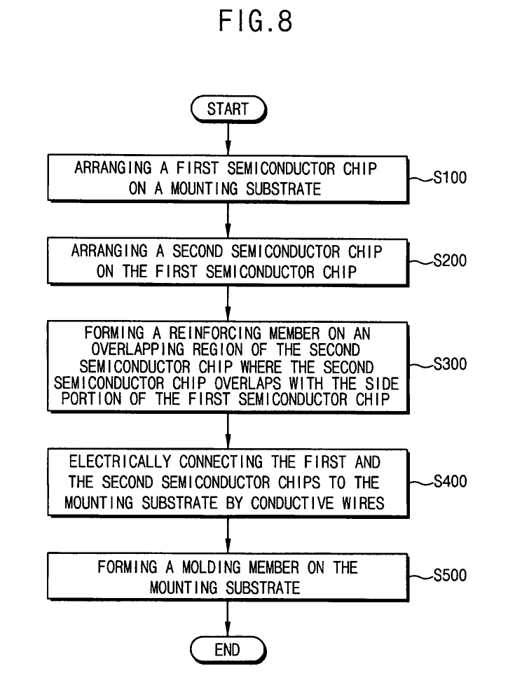

FIG. 8 is a flow chart illustrating a method of manufacturing the multi-chip package of FIG. 2.

Referring to FIG. 8, first, a first semiconductor chip is positioned on a mounting substrate (Step S100). For example, an epoxy material or polyimide may be coated on the mounting substrate, and may be cured to adhere the first semiconductor chip to the mounting substrate.

Then, a second semiconductor chip is arranged on the first semiconductor chip such that an end portion of the second semiconductor chip protrudes from a side portion of the first semiconductor chip (Step S200). For example, an epoxy material or polyimide may be coated on the first semiconductor chip, and may be cured to adhere the second semiconductor chip to the first semiconductor chip. The first and the second semiconductor chips may be adhered by a eutectic die bonding process, a soft solder die bonding process, a tape bonding process, etc.

The size of the second semiconductor chip may be different from that of the first semiconductor chip. For example, the size of the second semiconductor chip may be larger than that of the first semiconductor chip. Alternatively, the size of the second semiconductor chip may be substantially the same as that of the first semiconductor chip.

The first and the second semiconductor chips may have a rectangular shape, respectively. A longitudinal direction of the second semiconductor chip may be substantially perpendicular to a longitudinal direction of the first semiconductor chip. The first and the second semiconductor chips may cross each other, and thus, an end portion of the second semiconductor chip may protrude from a side portion of the first semiconductor chip. Accordingly, the second semiconductor chip may have an overhang portion protruding from the first semiconductor chip.

After the second semiconductor chip is adhered to the second semiconductor chip, a reinforcing member is formed on an overlapping region of the second semiconductor chip where the second semiconductor chip overlaps with the side portion of the first semiconductor chip (Step S300). The reinforcing member may decrease bending downward of the overhang portion of the second semiconductor chip protruding from the side portion of the first semiconductor chip. In this case, the overlapping region of the second semiconductor chip where the second semiconductor chip overlaps with the side portion of the first semiconductor chip may be a region where the overhang portion of the second semiconductor chip begins to protrude from the first semiconductor chip.

For example, a liquefied epoxy resin may be coated on the overlapping region of the second semiconductor chip to form the reinforcing member. Alternatively, an adhesive film may be coated on the overlapping region of the second semiconductor chip to form the reinforcing member.

After the reinforcing member is formed on the second semiconductor chip, the first and the second semiconductor chips are electrically connected to the mounting substrate, respectively (Step S400).

A plurality of bond fingers is formed on the mounting substrate, a plurality of first bonding pads is formed on the first semiconductor chip, and a plurality of second bonding pads is formed on the second semiconductor chip. For example, the first and the second semiconductor chips may be electrically connected to the mounting substrate by a wire bonding process, respectively. In the wire bonding process, the first and the second bonding pads may be electrically connected to the bond fingers of the mounting substrate with conductive wires. For example, the conductive wires may include a conductive material such as gold, aluminum, etc.

Then, a molding member is formed on the mounting substrate to protect the first and the second semiconductor chips from external impact (Step S500). For example, the molding member 600 may be formed using epoxy mold compound (EMC).

In another example embodiment, before the first semiconductor chip is adhered to the mounting substrate, a third semiconductor chip may be positioned on the mounting substrate. An end portion of the first semiconductor chip may protrude from a side portion of the third semiconductor chip. A longitudinal direction of the first semiconductor chip may be substantially perpendicular to a longitudinal direction of the third semiconductor chip.

In another example embodiment, after the third semiconductor chip is adhered between the first semiconductor chip and the mounting substrate, an auxiliary reinforcing member may be further formed on the first semiconductor chip such that the auxiliary reinforcing member makes contact with a side portion of the second semiconductor chip. The auxiliary reinforcing member may decrease bending downward of the first semiconductor chip from the side portion of the third semiconductor chip.

The auxiliary reinforcing member may be formed on an overhang portion of the first semiconductor chip where the first semiconductor chip protrudes from the side portion of the third semiconductor chip. Alternatively, the auxiliary reinforcing member may be formed on an overlapping region of the first semiconductor chip where the first semiconductor chip overlaps with the side portion of the third semiconductor chip. The auxiliary reinforcing member may be arranged near the side portion of the second semiconductor chip.

For example, liquefied epoxy resin may be coated on the first semiconductor chip to form the auxiliary reinforcing member. Alternatively, an adhesive film may be coated on the first semiconductor chip to form the reinforcing member.

Then, a trim process for dividing the mounting substrate into individual devices and a marking process for printing a trademark and a product number on an outer surface thereof may be performed over the mounting substrate to complete a semiconductor package.

As mentioned above, according to example embodiments of the present invention, a multi-chip package includes the first and the second semiconductor chips stacked sequentially on the mounting substrate, and the reinforcing member formed on the overlapping region of the second semiconductor chip where the second semiconductor chip overlaps with the side portion of the first semiconductor chip. Accordingly, in a subsequent wire bonding process, the reinforcing member may decrease flexing of the overhang portion of the second semiconductor chip protruding from the first semiconductor chip to thereby prevent a crack from generating in the overhang portion. Thus, failures in a process of manufacturing the multi-chip package may be decreased so as to improve a process throughput.

According to one aspect of the present invention, a multi-chip package includes a mounting substrate, a first semiconductor chip, a second semiconductor chip, a reinforcing member, conductive wires and a molding member. The first semiconductor chip is arranged on the mounting substrate. The second semiconductor chip is arranged on the first semiconductor chip. An end portion of the second semiconductor chip protrudes from a side portion of the first semiconductor chip. The reinforcing member is formed on an overlapping region of the second semiconductor chip where the second semiconductor chip overlaps with the side portion of the first semiconductor chip such that the reinforcing member decreases downward bending of the second semiconductor chip from the side portion of the first semiconductor chip. The conductive wires electrically connect the first and the second semiconductor chips to the mounting substrate. The molding member is formed on the mounting substrate to cover the first and second semiconductor chips and the conductive wires.

In one example embodiment, the reinforcing member may include an epoxy material.

In another example embodiment, the reinforcing member may be formed on a substantially entire region of the second semiconductor chip where the second semiconductor chip overlaps with the first semiconductor chip.

In still another example embodiment, the multi-chip package may further include a third semiconductor chip arranged between the first semiconductor chip and the mounting substrate. An end portion of the first semiconductor chip protrudes from a side portion of the first semiconductor chip.

In still another example embodiment, the multi-chip package may further include an auxiliary reinforcing member formed on the first semiconductor chip such that the auxiliary reinforcing member decrease downward bending of the first semiconductor chip from the side portion of the third semiconductor chip.

In one example embodiment, the auxiliary reinforcing member may include an epoxy material.

According to another aspect of the present invention, there is provided a method of manufacturing a multi-chip package. In the method of manufacturing a multi-chip package, a first semiconductor chip is arranged on a mounting substrate. A second semiconductor chip is arranged on the first semiconductor chip. An end portion of the second semiconductor chip protrudes from a side portion of the first semiconductor chip. A reinforcing member is formed on an overlapping region of the second semiconductor chip where the second semiconductor chip overlaps with the side portion of the first semiconductor chip such that the reinforcing member decreases downward bending of the second semiconductor chip from the side portion of the first semiconductor chip. The first and the second semiconductor chips are electrically connected to the mounting substrate with conductive wires. A molding member is formed on the mounting substrate to protect the first and the second semiconductor chips from external impact.

In another example embodiment, the method of manufacturing a multi-chip package may further include arranging a third semiconductor chip on the mounting substrate before arranging the first semiconductor chip on the mounting substrate. An end portion of the first semiconductor chip protrudes from a side portion of the third semiconductor chip.

In another example embodiment, the method of manufacturing a multi-chip package may further include forming an auxiliary reinforcing member on the first semiconductor chip such that the auxiliary reinforcing member decreases downward bending of the first semiconductor chip from the side portion of the third semiconductor chip.

According to the present invention, the multi-chip package includes the first and the second semiconductor chips stacked sequentially on the mounting substrate, and the reinforcing member formed on the overlapping region of the second semiconductor chip where the second semiconductor chip overlaps with the side portion of the first semiconductor chip. Accordingly, in a subsequent wire bonding process, the reinforcing member may decrease flexing of the overhang portion of the second semiconductor chip protruding from the first semiconductor chip to thereby prevent a crack from being generated in the overhang portion.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A multi-chip package comprising:
a mounting substrate;
a first semiconductor chip disposed on the mounting substrate;
a second semiconductor chip disposed on the first semiconductor chip, an end portion of the second semiconductor chip protruding from a side portion of the first semiconductor chip;
a reinforcing member disposed on an overlapping region of the second semiconductor chip where the second semiconductor chip overlaps with the side portion of the first semiconductor chip;
conductive wires electrically connecting the first and the second semiconductor chips to the mounting substrate; and
an encapsulant disposed on the mounting substrate so as to cover the first and the second semiconductor chips and the conductive wires.

2. The multi-chip package of claim 1, wherein the reinforcing member comprises an epoxy material.

3. The multi-chip package of claim 1, wherein the reinforcing member is disposed on an substantially entire region of the second semiconductor chip where the second semiconductor chip overlaps with the first semiconductor chip.

4. The multi-chip package of claim 1, wherein the first semiconductor chip is adhered to the mounting substrate by a first adhesive layer and the second semiconductor chip is adhered to the first semiconductor chip by a second adhesive layer.

5. The multi-chip package of claim 4, wherein the first and the second adhesive layers comprise a liquefied adhesive or an adhesive film.

6. The multi-chip package of claim 1, further comprising a third semiconductor chip disposed between the first semiconductor chip and the mounting substrate, wherein an end portion of the first semiconductor chip protrudes from a side portion of the third semiconductor chip.

7. The multi-chip package of claim 6, further comprising an auxiliary reinforcing member formed on the first semiconductor chip.

8. The multi-chip package of claim 7, wherein the auxiliary reinforcing member comprises an epoxy material.

9. The multi-chip package of claim 7, wherein the auxiliary reinforcing member is disposed on an overlapping region of the first semiconductor chip where the first semiconductor chip overlaps with the side portion of the third semiconductor chip.

10. The multi-chip package of claim 7, wherein the auxiliary reinforcing member is disposed adjacent to a sidewall of the second semiconductor chip.

11. The multi-chip package of claim 1, wherein the reinforcing member is disposed on a diagonal region of the second semiconductor chip.
